(19) United States
(12) Patent Application Publication
(10) Pub. No.: US 2010/0300735 A1
(43) Pub. Date: Dec. 2, 2010

(54) PRINTED CIRCUIT BOARD

(75) Inventor: Chang-Te Liao, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/542,824

(22) Filed: Aug. 18, 2009

(30) Foreign Application Priority Data
Jun. 2, 2009 (CN) 200920303919.2

(51) Int. Cl. H05K 1/09

(52) U.S. Cl. 174/257

(57) ABSTRACT

A printed circuit board (PCB) includes a substrate, a plurality of copper foils formed on at least one surface of the substrate, a plurality of through holes extending through the substrate arranged in a rectangular array, and a plurality of blocking wall. Inner walls of the plurality of through holes are coated with the plurality of copper foils. The plurality of blocking walls project from the plurality of copper foils and surround the plurality of through holes to prevent solder from overflowing into the plurality of through holes when the PCB goes through a wave soldering procedure.

### BACKGROUND

1. Technical Field

The present disclosure relates to circuit boards, and more particularly to a printed circuit board (PCB) with blocking walls.

2. Description of Related Art

Electronic devices, such as mobile phones, personal digital assistants (PDA), routers, and switches, for example, utilize a plurality of printed circuit boards (PCBs) to perform different functions. Frequently, a PCB includes a plurality of vias and a plurality of electrical components soldered on the PCB. However, the solder is prone to flow into the vias when the PCB goes through a wave soldering procedure so that air is trapped in the vias. Thus, the air expands and applies pressure on the electronic components when the PCB goes through a reflow procedure, causing the electrical components to disengage from the PCB.

Therefore, a need exists in the industry to overcome the described limitations.

### BRIEF DESCRIPTION OF THE DRAWINGS

FIG. 1 is a top view of a printed circuit board (PCB) in accordance with the present disclosure;

FIG. 2 is a cross-sectional view as taken along line II-II in FIG. 1; and

FIG. 3 is an assembled view of an electronic component soldered on the PCB of FIG. 2.

### DETAILED DESCRIPTION

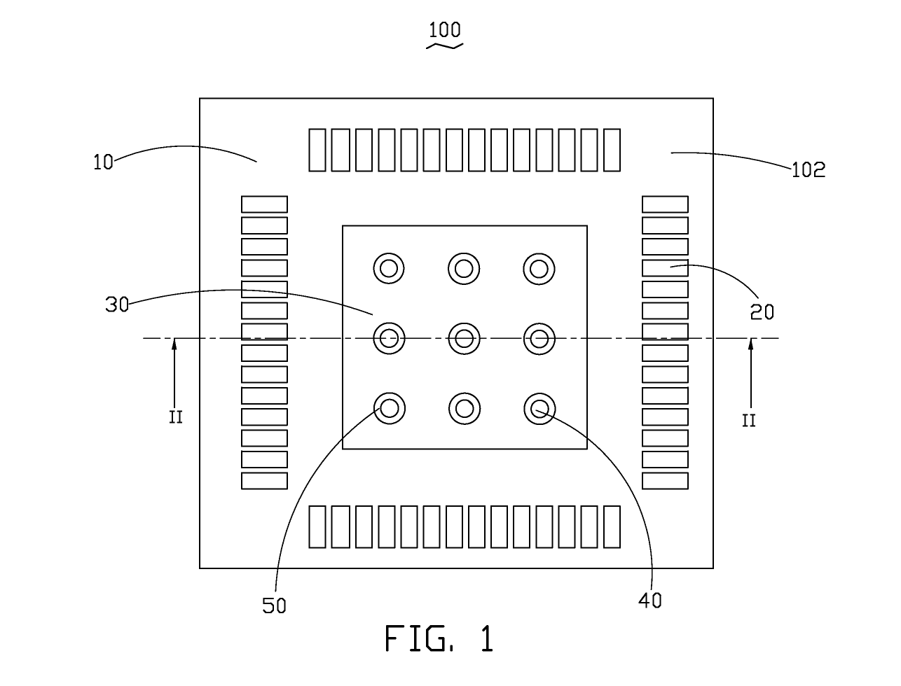

FIG. 1 is a top view of a printed circuit board (PCB) 100 in accordance with the present disclosure. The PCB 100 includes a substantially non-conductive substrate 10, a plurality of golden fingers 20, a plurality of copper foils 30, a plurality of through holes 40, and a plurality of substantially non-conductive blocking walls 50.

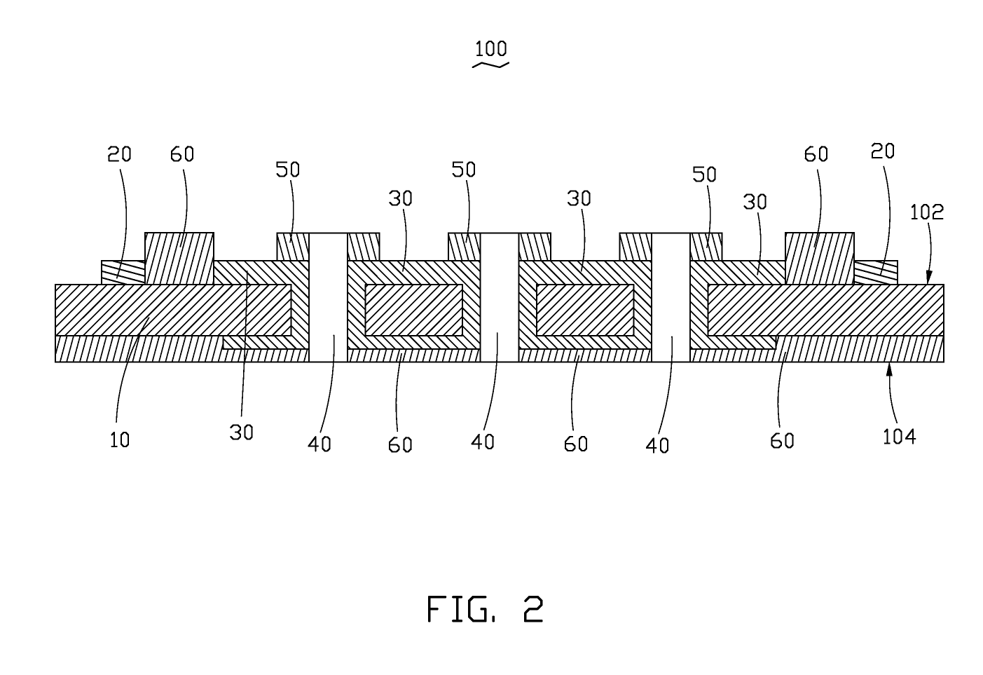

FIG. 2 is a cross-sectional view as taken along line II-II in FIG. 1. The substrate 10 includes a first surface 102 and a second surface 104 parallel to the first surface 102. A non-conductive solder mask layer 60 covers the second surface 104, and an area between the plurality of copper foils 30 and the plurality of through holes 40.

The plurality of golden fingers 20 are disposed on the first surface arranged in four rows, and surround the copper foil 30 therein. Alternatively, the plurality of golden fingers 20 may be disposed on the first surface 102 arranged in one, two, or three rows.

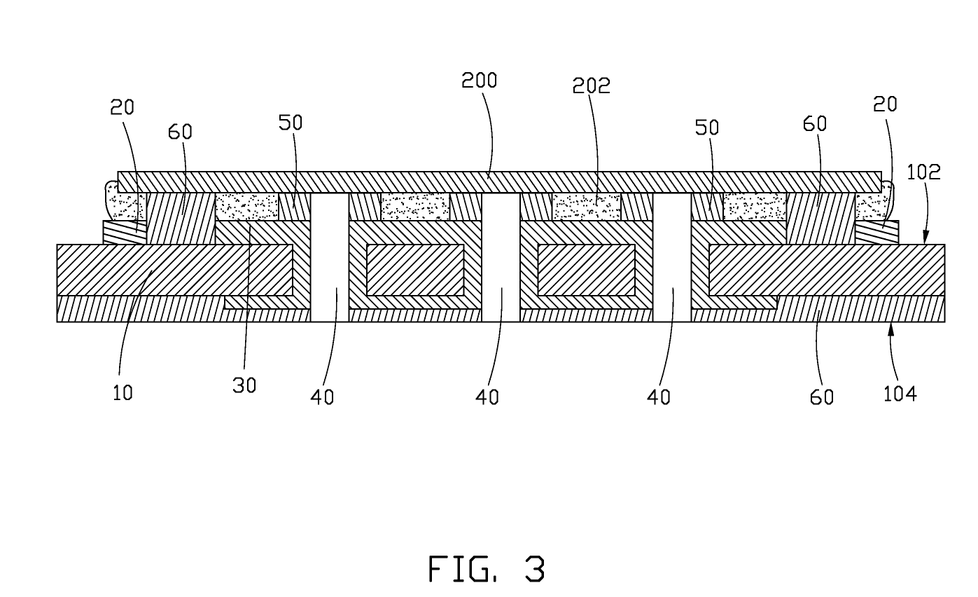

The plurality of copper foils 30 are disposed on the first surface 102 so that an electronic component 200, such as an integrated circuit (IC), can be soldered on the plurality of copper foil 30 with solder 202 (referring to FIG. 3).

Alternatively, the copper foil 30 may be disposed on the second surface 104 or the first surface 102 and the second surface 104.

The plurality of through holes 40 extends through the substrate 10 arranged in a rectangular array. Inner walls of the plurality of through holes 40 are coated with the plurality of copper foils 30. In the illustrated embodiment, the plurality of through holes 40 may be vias or mounting holes. Each of the plurality of blocking walls 50 projects from the plurality of copper foils 30 arranged in a circle and surrounds each of the plurality of through holes 40. The plurality of blocking walls 50 are positioned so as to prevent the solder 202 from overflowing into the plurality of through holes 40 when the PCB 100 goes through a wave soldering procedure.

In the illustrated embodiment, each of the plurality of blocking walls 50 may be an annular solder mask, and disposed on the second surface 104 or the first surface 102 and the second surface 104.

Each of the plurality of blocking walls 50 surrounds the corresponding through hole 40 so that no solder 202 overflows into the plurality of through holes 40 when the PCB 100 goes through the wave soldering procedure. That is, the plurality of blocking walls 50 prevent the solder 202 from overflowing into the plurality of through holes when the PCB goes through a wave soldering procedure. Thus, air will not be trapped in the plurality of through holes 40, avoiding disengagement of the electronic component 200 from the substrate 10.

While an embodiment of the present disclosure has been described above, it should be understood that it has been presented by way of example only and not by way of limitation. Thus the breadth and scope of the present disclosure should not be limited by the above-described embodiments, but should be defined only in accordance with the following claims and their equivalents.

What is claimed is:

1. A printed circuit board (PCB) comprising:
a substrate;
a plurality of copper foils formed on at least one surface of the substrate;
a plurality of through holes extending through the substrate arranged in a rectangular array, wherein inner walls of the plurality of through holes are coated with the plurality of copper foils; and
a plurality of blocking walls projecting from the plurality of copper foils and surrounding the plurality of through holes to prevent solder from overflowing into the plurality of through holes when the PCB goes through a wave soldering procedure.

2. The PCB of claim 1, wherein each of the plurality of blocking walls is made of a solder mask layer.

3. The PCB of claim 2, further comprising a plurality of golden fingers disposed on the at least one surface of the substrate.

4. The PCB of claim 1, wherein a solder mask layer covers an area between the plurality of copper foils and the plurality of golden fingers.
